(19) United States
(12) Patent Application Publication
(10) Pub. No.: US 2019/0361340 A1
(43) Pub. Date: Nov. 28, 2019

(54) SEMICONDUCTOR IMPRINT DEVICE AND OPERATING METHOD OF SEMICONDUCTOR IMPRINT DEVICE

(71) Applicant: SAMSUNG ELECTRONICS CO., LTD., SUWON-SI (KR)

(72) Inventors: HO YU, POHANG-SI (KR); BYEONGSANG KIM, HWASEONG-SI (KR); KYUNGBIN PARK, SEOUL (KR)

(21) Appl. No.: 16/207,819

(22) Filed: Dec. 3, 2018

(30) Foreign Application Priority Data
May 28, 2018 (KR) 10-2018-00060285

(51) Int. Cl. G03F 7/00; G03F 9/00; B29C 59/04; B29C 59/02

(52) U.S. Cl. CPC G03F 7/0002; B29C 59/022; B29C 59/046; G03F 9/7049

(57) ABSTRACT

A semiconductor imprint device includes a stage that supports a substrate, a film clamp that applies a film stamp including a pattern onto the substrate, a roller that applies pressure to the film stamp disposed on the substrate so that the pattern is transferred to the substrate, a camera that captures an image of the roller and the film stamp, and a controller that adjusts a position of the film clamp by using the image. The pattern is for forming a semiconductor device.

### CROSS-REFERENCE TO RELATED APPLICATIONS

This U.S. non-provisional application claims priority under 35 U.S.C. § 119 to Korean Patent Application No. 10-2018-0060285 filed on May 28, 2018, in the Korean Intellectual Property Office, the disclosure of which is incorporated by reference in its entirety herein.

### BACKGROUND

### 1. Technical Field

Embodiments of the inventive concept relate to a semiconductor manufacturing device, and more particularly, relate to a semiconductor imprint device having improved yield and reduced manufacturing costs and an operating method of the semiconductor imprint device.

### 2. Discussion of Related Art

Various manufacturing methods may be used to manufacture a semiconductor device. Methods for manufacturing a semiconductor device include an imprint method. According to the imprint method, a semiconductor device is manufactured by printing a specific pattern for forming a semiconductor device on a medium by using a stamp having the specific pattern.

The stamp and the medium may be in contact with each other for the purpose of carrying out the imprint method. Voids such as air bubbles may occur when the stamp and the medium are in contact with each other. The voids may cause the semiconductor device to be manufactured with a defect, thereby reducing the yield (i.e., the quantity produced).

Also, the stamp may deteriorate the more times it is used to manufacture a semiconductor device. When the deterioration of the stamp progresses too far, there is a need to prepare a new stamp, and thus, manufacturing costs of the semiconductor device may increase.

### SUMMARY

At least one embodiment of the inventive concept provides a semiconductor imprint device which increases the yield and reduces manufacturing costs by managing a stamp in the process of manufacturing a semiconductor device and an operating method of the semiconductor imprint device.

According to an exemplary embodiment of the inventive concept, a semiconductor imprint device includes a stage that supports a substrate, a film clamp that applies a film stamp including a pattern onto the substrate, a roller that applies pressure to the film stamp disposed on the substrate so that the pattern is transferred to the substrate, a camera that captures an image of the roller and the film stamp, and a controller that adjusts a position of the film clamp by using the image.

According to an exemplary embodiment of the inventive concept, a semiconductor imprint device includes a stage that supports a substrate, an applicator configured to apply a resin onto the substrate, a film clamp configured to apply a film stamp including a pattern onto the resin, a first roller configured to apply a first pressure to the film stamp disposed on the substrate so that the pattern is transferred to the resin, a second roller configured to apply a second pressure to the film stamp so that contact of the film stamp and the resin between the first roller and the second roller is maintained, a lamp configured to project light onto the resin through the film stamp between the first roller and the second roller, a camera configured to capture an image of the first roller and the film stamp, and a controller configured to adjust a position of the film stamp by using the image so that a tension of the film stamp between the first roller and the film clamp is maintained within a specific range.

According to an exemplary embodiment of the inventive concept, a method of operating a semiconductor imprint device is provided. The semiconductor imprint device includes a film clamp and a roller. The method includes applying a film stamp onto a substrate by using the film clamp, applying pressure to the film stamp by using the roller, a camera of the semiconductor imprint device capturing an image associated of the roller and the film stamp, and a controller of the semiconductor imprint device adjusting a position of the film clamp by using the image.

According to an exemplary embodiment, a device for imprinting a semiconductor pattern onto a substrate is provided. The device includes a film clamp having a film stamp extending from an edge of the film clamp, the film stamp including the semiconductor pattern. The device further includes a roller, a camera, and a controller. The controller is configured to move the film clamp to a first position, move the roller to apply pressure to the film stamp until an area of the film clamp including the pattern contacts the substrate, control the camera to capture an image of an interface of the roller and the film stamp, determine a tension in the film stamp based on the captured image, and move the film clamp to a second position different from the first position when the determined tension is outside a predetermined range.

### BRIEF DESCRIPTION OF THE FIGURES

The inventive concept will become apparent by describing in detail exemplary embodiments thereof with reference to the accompanying drawings.

FIG. 1 is a view illustrating a semiconductor imprint device according to an exemplary embodiment of the inventive concept.

FIG. 2 is a view illustrating an example in which a controller according to an embodiment of the inventive concept controls a roller.

FIG. 3 is a flowchart illustrating an operating method of a semiconductor imprint device according to an exemplary embodiment of the inventive concept.

FIG. 4 is a view illustrating an example in which tension of a film stamp is measured as being excessive.

FIG. 5 is a view illustrating an example in which tension of a film stamp is measured as being too small.

FIG. 6 is a view illustrating an example in which tension of a film stamp is measured as being excessive.

FIG. 7 is a view illustrating an example in which tension of a film stamp is measured as being too small.

FIG. 8 is a view illustrating a semiconductor imprint device according to an exemplary embodiment of the inventive concept.

FIG. 9 is a view illustrating an example in which a machine learning classifier performs a machine learning-based classification.

FIG. 10 is a view illustrating an example in which a machine learning classifier performs a machine learning-based classification.

FIG. 11 is a view illustrating an example in which a machine learning classifier performs a machine learning-based classification.

FIG. 12 is a view illustrating a semiconductor imprint device according to an exemplary embodiment of the inventive concept.

### DETAILED DESCRIPTION OF THE EMBODIMENTS

Hereinafter, exemplary embodiments of the inventive concept in conjunction with accompany drawings will be described. Below, details, such as detailed configurations and structures, are provided to aid a reader in understanding embodiments of the inventive concept. Therefore, embodiments described herein may be variously changed or modified without departing from embodiments of the inventive concept. The same reference numeral indicates the same part throughout the accompany drawings.

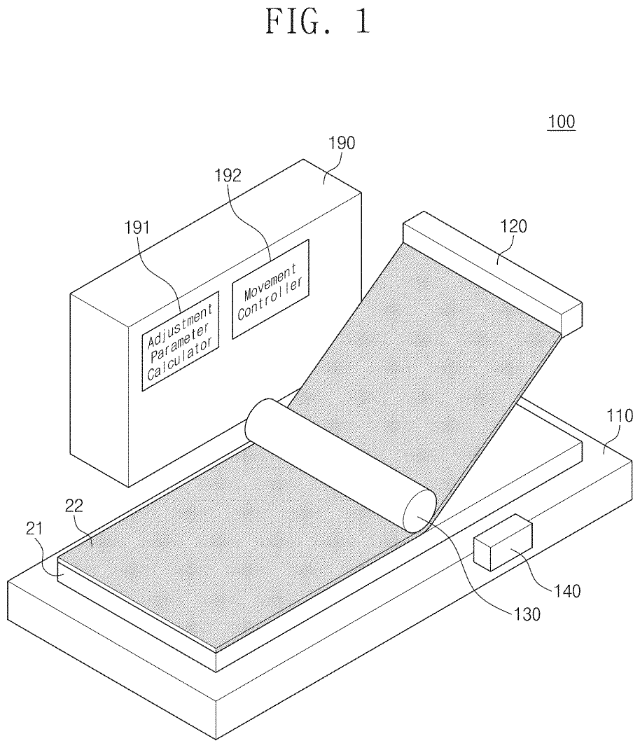

FIG. 1 is a view illustrating a semiconductor imprint device 100 according to an exemplary embodiment of the inventive concept. Referring to FIG. 1, the semiconductor imprint device 100 includes a stage 110, a film clamp 120, a roller 130, a camera 140, and a controller 190. In an embodiment, the controller 190 includes one or more actuators to move at least one of the stage 110, the film clamp 120, the roller 130, and the camera 140, and includes a processor or microprocessor to control the camera 140, perform calculations based on image(s) captured by the camera and/or additional measured or learned parameters, and control the actuators based on results of those calculations. In an exemplary embodiment, the stage 110 is omitted from the imprint device 100 so that the imprint device 100 can be applied to an external stage.

The stage 110 is configured to support a substrate 21 for a semiconductor device. For example, the substrate 21 may be made of a semiconductor material or a glass material. While the stage 110 supports the substrate 21, a semiconductor imprinting process is performed on the substrate 21.

The film clamp 120 is configured to provide a film stamp 22. For example, the film clamp 120 may be spaced from the stage 110 and may be initially positioned above the stage 110. For example, upon placing the substrate 21 on the stage 110, the film clamp 120 may be spaced away from the substrate 21 and may be positioned above the substrate 21.

The film clamp 120 applies the film stamp 22 onto the stage 110. For example, upon placing the substrate 21 on the stage 110, the film clamp 120 moves(provides or emits) the film stamp 22 toward the substrate 21. The film clamp 120 may be moved from an edge of the substrate 21 to another edge of the substrate 21 while providing(or emitting) the film stamp 22 such that the film stamp 22 contacts the substrate 21 sequentially from the edge to the another edge. The film clamp 120 may include one or more rollers to move the film stamp 22 toward contact with the stage 110. The roller(s) may be used to apply pressure to an area of the film stamp 22 such that the film stamp 22 is maintained as flat when just provided or emitted from the film clamp 120.

The roller 130 may be initially positioned above the stage 110. For example, in a standby step, the roller 130 is spaced away from the stage 110 and positioned above the stage 110. In an embodiment of a manufacturing step where the substrate 21 is positioned on the stage 110, the roller 130 is positioned on the substrate 21 to be in close contact with the film stamp 22 provided on the substrate 21.

In an embodiment, the roller 130 applies pressure (e.g., physical force) to the film stamp 22 so that the film stamp 22 is brought into close contact with the substrate 21. For example, the roller 130 may apply pressure to the film stamp 22 depending on gravity by using its own weight.

In an embodiment, the film stamp 22 includes a fine pattern for manufacturing a semiconductor device. When the pressure is applied to the film stamp 22 by the roller 130, the pattern of the film stamp 22 is transferred to the substrate 21. That is, the pattern may be formed in or on the substrate 21. The semiconductor imprint device 100 manufactures a semiconductor device by transferring the pattern of the film stamp 22 to the substrate 21.

The semiconductor imprint device 100 according to an embodiment of the inventive concept includes the camera 140 (e.g., a camera system including one or more cameras). The camera 140 may capture an image associated with the roller 130 and the film stamp 22. For example, the camera may capture an image where the roller 130 interfaces with the film stamp 22. For example, the camera 140 may include two or more cameras. In an embodiment, distances of the two or more cameras from the roller 130 are different from each other. In an embodiment, the camera 140 includes two or more cameras positioned on opposite sides of the roller 130. The image(s) captured by the camera 140 may be transferred to the controller 190. For example, a cable (not shown) may connect the camera 140 to the controller 190 and be used to transfer the image from the camera 140 to the controller 190. In another embodiment, the camera 140 and the controller 190 each include a transceiver so the image can be wirelessly transmitted from the camera 140 to the controller 190. In an exemplary embodiment, the roller 130 has a cylindrical shape including opposing circular flat surfaces coupled with a curved tubular (non-flat) surface, one of the cameras is positioned spaced apart from a first one of the flat surfaces to face the first flat surface and another one of the cameras is positioned spaced apart from the second other flat surface to face the second flat surface.

The controller 190 may control a manufacturing process of the semiconductor imprint device 100. For example, the controller 190 may control the manufacturing process such that the film stamp 22 is applied onto the substrate 21 and the pattern of the film stamp 22 is transferred to the substrate 21, by moving the film clamp 120 and the roller 130 in a specific direction, for example, in a right direction in FIG. 1. In an embodiment, the controller 190 moves the camera 140 together with the roller 130.

For example, the controller 190 may control the manufacturing process such that the film stamp 22 is applied onto the substrate 21 and the pattern of the film stamp 22 is transferred to the substrate 21, by moving the stage 110 in a specific direction, for example, in a left direction in FIG. 1. In an embodiment, the controller 190 keeps the camera 140 and the roller 130 at a fixed position.

The controller 190 may receive the image associated with the roller 130 and the film stamp 22 from the camera 140. The controller 190 may adjust the tension of the film stamp 22 by using the received image. For example, the controller 190 may adjust the tension of the film stamp 22 by adjusting a position of the film clamp 120. The adjusting of the position may include moving the film clamp 120 from a first position having a first tension to a second position different from the first position having a second tension different from the first tension.

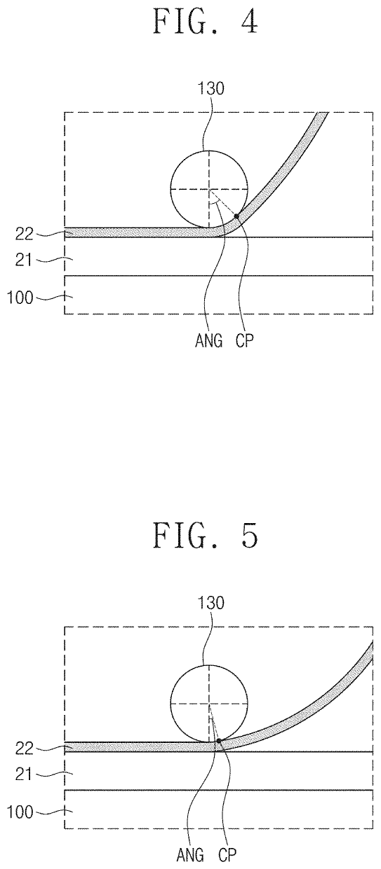

In the manufacturing process, the yield of the semiconductor imprint device 100 and costs needed for the semiconductor imprint device 100 to manufacture a semiconductor device may vary with the tension of the film stamp 22. The semiconductor imprint device 100 according to an embodiment of the inventive concept adjusts the tension of the film stamp 22, thus improving the yield and reducing the manufacturing costs. This will be further described with reference to FIGS. 4 to 7.

The controller 190 includes an adjustment parameter calculator 191 and a movement controller 192. The adjustment parameter calculator 191 may analyze the image received from the camera 140. Depending on a result of the image analysis, the adjustment parameter calculator 191 may calculate an adjustment parameter indicating how to move the film clamp 120. The adjustment parameter calculator 191 may be implemented by a processor of the controller 190.

The movement controller 192 may receive the adjustment parameter from the adjustment parameter calculator 191. In an embodiment, the movement controller 192 adjusts the movement of the film clamp 120 depending on the adjustment parameter. For example, in FIG.

1, the movement controller 192 may adjust the film clamp 120 up, down, left, right, or in any direction of two directions thereof. For example, the movement controller 192 may adjust a height of the film clamp 120 above the stage 110 or a distance between the film clamp 120 and the roller 130. For example, the movement controller 192 may be implemented by one or more actuators or motors to adjust the position of the film clamp 120.

For example, when the controller 190 moves the film clamp 120 and the roller 130 in a specific direction for the purpose of applying the film stamp 22 onto the substrate 21 and transferring a pattern to the substrate 21, it may be understood as the controller 190 adjusting a speed at which the film clamp 120 moves depending on the adjustment parameter.

The movement controller 192 may maintain the tension of the film stamp 22 within a specific range by adjusting the position of the film clamp 120 or speed at which the film clamp 120 is moved. Accordingly, the yield of the semiconductor imprint device 100 is improved, and the manufacturing costs are reduced.

In an embodiment, the tension in the film stamp 22 is measured by positioning a tension sensor on the film clamp 120. In an embodiment, the measured tension indicates the tension of a nozzle through which the film clamp 120 discharges the film stamp 22. For example, the film stamp 22 may extend from or protrude from an edge or an opening of the film clamp 120. The tension of the film stamp 22 at an interface where the film stamp 22 and the roller 130 are in contact with each other may affect the yield of the semiconductor imprint device 100. In an embodiment, one end of the film stamp 22 is attached to one end of the film clamp 120.

The semiconductor imprint device 100 according to an embodiment of the inventive concept captures an image associated with the roller 130 and the film stamp 22 and calculates the tension of the film stamp 22 at the interface where the film stamp 22 and the roller 130 are in contact with each other. For example, the controller 190 may calculate the tension of the film stamp 22 at a portion, which is the most adjacent to the film stamp 22, of the interface where the film stamp 22 and the roller 130 are in contact with each other. For example, the portion may be located on an outermost edge of the film stamp 22.

Accordingly, the tension of the film stamp 22 is calculated more exactly, and the tension of the film stamp 22 is adjusted more exactly. This means that the yield of the semiconductor imprint device 100 is improved and costs needed for the semiconductor imprint device 100 to manufacture a semiconductor device is further reduced.

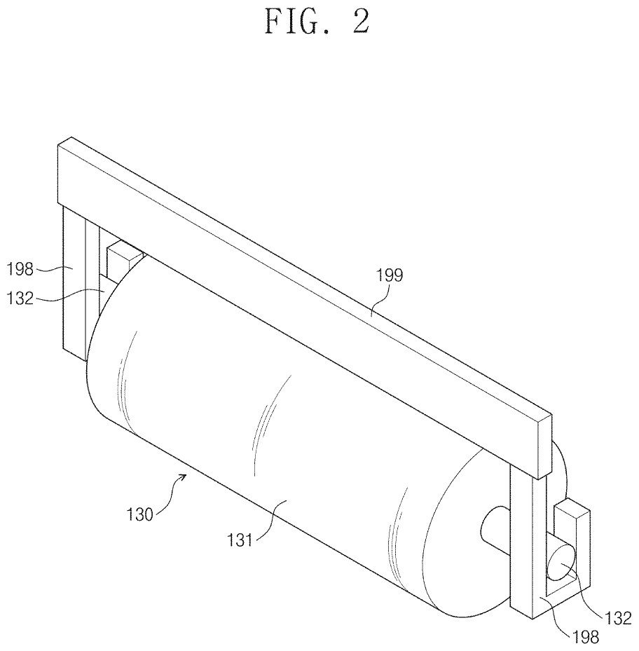

FIG. 2 is a view illustrating an example in which the controller 190 according to an embodiment of the inventive concept controls the roller 130. Referring to FIGS. 1 and 2, the roller 130 includes a roller body 131 and roller push rods 132. In an embodiment, the roller push rods 132 protrude from the roller body 131 at opposite sides of the roller body 131.

In an embodiment, the controller 190 moves the roller 130 by using a moving bar 199 and roller racks 198. In an embodiment, the roller racks 198 surround left, right, and lower ends of the roller push rods 132 of the roller 130.

In an embodiment, the controller 190 lifts the roller 130 from the stage 110 or the substrate 21 by lifting the moving bar 199 upwardly. The controller 190 may also lower the roller 130 by lowering the moving bar 199 downwardly. The controller 190 allows the roller 130 to be in close contact with the film stamp 22 on the substrate 21, which is positioned above the stage 110, by lowering the moving bar 199 downwardly. In an embodiment, the controller 190 includes a first motor to lift and lower the moving bar 199. In an embodiment, the controller 190 includes the first motor and a second motor to move a position of the film clamp 120 in an upward direction, in a downward direction, in a left direction, or in a right direction.

In an embodiment, when the controller 190 moves the roller 130 in a specific direction in a manufacturing process, the controller 190 moves the moving bar 199 in same the specific direction. In another embodiment, the controller 190 is capable of moving the stage 110 in a specific direction (e.g., upwardly and/or downwardly). For example, when the controller 190 moves the stage 110 in the specific direction in a manufacturing process, the controller 190 fixes a position of the moving bar 199.

When the controller 190 artificially applies the pressure which allows the roller 130 to be in close contact with the film stamp 22, the pressure transmitted from the roller 130 to the film stamp 22 may not be uniform. For example, the pressure transmitted to the film stamp 22 from a portion to which the controller 190 applies the pressure may be greater than the pressure transmitted to the film stamp 22 from a portion to which the controller 190 does not apply pressure.

To uniformly apply the pressure from the roller 130 to the film stamp 22, the controller 190 does not apply artificial pressure to the roller 130. As described with reference to FIG. 2, the controller 190 may put the roller 130 into a floating state by further raising the moving bar 199 and the roller racks 198 after the roller 130 is in close contact with the film stamp 22.

The roller 130 may apply pressure to the film stamp 22 only by using its own weight. When the roller 130 is manufactured so that the weight of the roller 130 is uniform depending on a position on the roller body 131, the roller 130 may uniformly apply pressure to the film stamp 22.

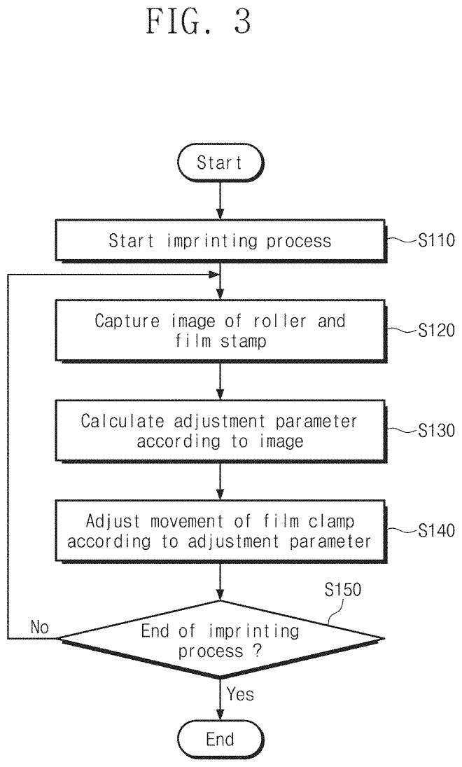

FIG. 3 is a flowchart illustrating an operating method of the semiconductor imprint device 100 according to an exemplary embodiment of the inventive concept. Referring to FIGS. 1 and 3, in operation S110, the semiconductor imprint device 100 starts an imprinting process. The film clamp 120 moves the film stamp 120 into contact with the substrate 21.

The roller 130 applies pressure to the film stamp 22 to transfer the pattern of the film stamp 22 to the substrate 21. The semiconductor imprint device 100 may transfer the pattern of the film stamp 22 on the whole of the substrate 21 by moving the film clamp 120 and the roller 130 or by moving the stage 110.

While the imprinting process is performed, the controller 190 may adjust the movement or a position of the film clamp 120 so that the tension of the film stamp 22 is maintained within a specific range. In operation S120, the camera 140 captures an image associated with the substrate 21, the film stamp 22, and the roller 130.

In operation 5130, the adjustment parameter calculator 191 (e.g., a processor) of the controller 190 calculates an adjustment parameter depending on the image. Examples of calculating the adjustment parameter depending on the image will be further described with reference to FIGS. 4 to 7. In operation 5140, the movement controller 192 of the controller 190 adjusts the movement of the film clamp 120 depending on the adjustment parameter.

In operation S150, the controller 190 determines whether the imprinting process has completed. Operation S120 and operation S140 may be repeatedly performed until the imprinting process has completed.

FIG. 4 is a view illustrating an example where the tension of the film stamp 22 is measured as being excessive. Referring to FIGS. 1 and 4, when the tension of the film stamp 22 is excessive, the film stamp 22 is tightened. In this case, the tension of the film stamp 22 may have an influence on the roller 130.

For example, as the tension of the film stamp 22 offsets a portion of the pressure of the roller 130, the pressure applied to the film stamp 22 by the roller 130 may be uneven. Due to the unevenness of the pressure, the pattern of the film stamp 22 may be unevenly transferred to the substrate 21, and thus, a defect may occur in the substrate 21.

Also, the tension of the film stamp 22 may allow the roller 130 to be lifted. When the roller 130 is lifted by the tension, the pattern of the film stamp 22 may not be transferred to the substrate 21, and thus, a defect may occur in the substrate 21. As such, when the tension of the film stamp 22 is excessive, a defect may occur in a semiconductor device manufactured by the semiconductor imprint device 100, and thus, the yield may decrease.

In addition, when the tension of the film stamp 22 is excessive, the film stamp 22 may be deformed. For example, the excessive tension may cause the film stamp 22 to deteriorate or to stretch. When the film stamp 22 is deformed, the film stamp 22 should be replaced before continuing to manufacture a semiconductor device. This means that manufacturing costs needed for the semiconductor imprint device 100 to manufacture a semiconductor device increase.

When the tension of the film stamp 22 is excessive, it is understood from FIG. 4 that an angle ANG between a normal of the roller 130 at a contact point CP, which is closest to the film clamp 120, of an interface between the roller 130 and the film stamp 22 and a line perpendicular to the substrate 21 exceeds a specific range.

The semiconductor imprint device 100 according to an embodiment of the inventive concept controls the movement of the film clamp 120 such that the angle ANG does not exceed a specific range, thus maintaining the tension of the film stamp 22 within a specific range and making it possible to increase the yield (or the quantity of semiconductor devices manufactured by the semiconductor imprint device 100) and to reduce manufacturing costs.

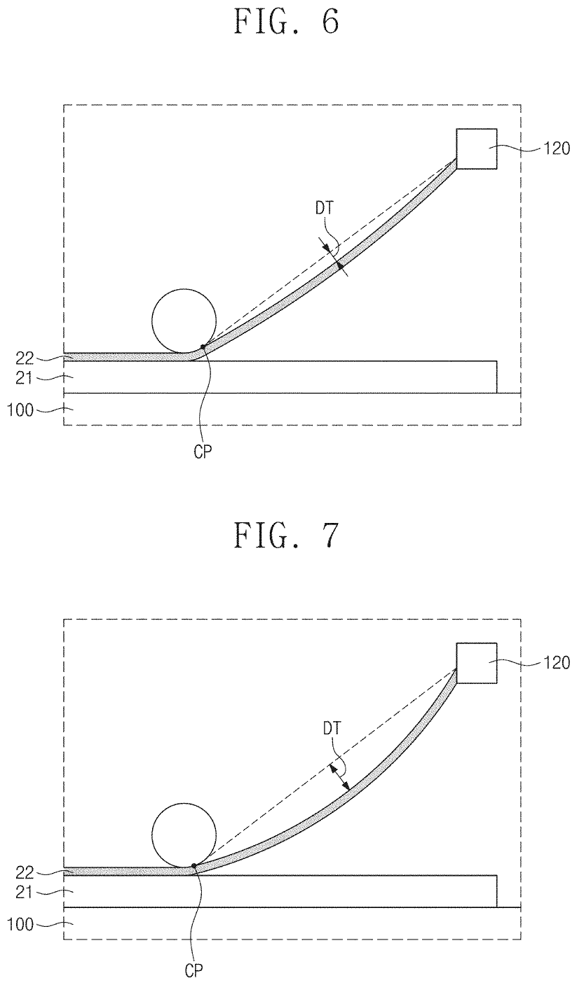

FIG. 5 is a view illustrating an example where the tension of the film stamp 22 is measured as being too small. Referring to FIGS. 1 and 5, when the tension of the film stamp 22 is too small, the film stamp 22 may stretch. When the film stamp 22 stretches, there may exist a portion of the film stamp 22, which is first in contact with the substrate 21 before contacting the roller 130.

When the film stamp 22 is first in contact with the substrate 21 before contacting the roller 130, a void such as an air bubble may occur between the film stamp 22 and the substrate 21. When the roller 130 applies pressure to the film stamp 22 after the film stamp 22 is first in contact with the substrate 21, a portion, which corresponds to the void, of the pattern of the film stamp 22 is not normally transferred to the substrate 21.

That is, a defect may occur in or on the substrate 21. As such, when the tension of the film stamp 22 is excessive, a defect may occur in a semiconductor device manufactured by the semiconductor imprint device 100, and thus, the yield may decrease. When the tension of the film stamp 22 is too small, it is understood from FIG. 5 that the angle ANG between a normal of the roller 130 and a line perpendicular to the substrate 21 is smaller than the specific range.

The semiconductor imprint device 100 according to an embodiment of the inventive concept controls the movement or position of the film clamp 120 such that the angle ANG is not smaller than the specific range, thus maintaining the tension of the film stamp 22 within a specific range and making it possible to increase the yield of the semiconductor imprint device 100.

FIG. 6 is a view illustrating an example where the tension of the film stamp 22 is measured as being excessive. Referring to FIGS. 1 and 6, when the tension of the film stamp 22 is excessive, the film stamp 22 is tightened. In this case, due to the tension of the film stamp 22, the yield (e.g., the quantity of semiconductor devices manufactured by the semiconductor imprint device 100) may decrease, and manufacturing costs may increase.

When the tension of the film stamp 22 is excessive, it is understood from FIG. 6 that a distance DT between the film stamp 22 and a line connecting a contact point CP of the roller 130 and a nozzle of the film clamp 120 is smaller than a specific range.

The semiconductor imprint device 100 according to an embodiment of the inventive concept controls the movement or position of the film clamp 120 so that the distance DT is not smaller than the specific range, thus maintaining the tension of the film stamp 22 within a specific range and making it possible to increase the yield of the semiconductor imprint device 100 and to reduce manufacturing costs.

FIG. 7 is a view illustrating an example where the tension of the film stamp 22 is measured as being too small. Referring to FIGS. 1 and 7, when the tension of the film stamp 22 is too small, the film stamp 22 may stretch. In this case, due to the tension of the film stamp 22, the yield (e.g., the quantity of semiconductor devices manufactured by the semiconductor imprint device 100) may decrease.

When the tension of the film stamp 22 is too small, it is understood from FIG. 7 that a distance DT between the film stamp 22 and a line connecting a contact point CP of the roller 130 and a nozzle of the film clamp 120 exceeds the specific range.

The semiconductor imprint device 100 according to an embodiment of the inventive concept controls the movement or position of the film clamp 120 so that the distance DT does not exceed the specific range, thus maintaining the tension of the film stamp 22 within a specific range and making it possible to increase the yield and to reduce manufacturing costs.

As described with reference to FIGS. 4 to 7, in an exemplary embodiment, the controller 190 is configured to detect the angle ANG and the distance DT from an image captured by the camera 140. In an embodiment, the controller 190 adjusts the movement of the film clamp 120 so that the angle ANG and the distance DT are not outside a specific range.

For example, when the distance DT decreases and the angle ANG increases due to an increase in the tension of the film stamp 22, the controller 190 may move the film clamp 120 to the left or down in FIG. 1. For example, when the film clamp 120 and the roller 130 moves in a specific direction in a manufacturing process, the controller 190 may decrease a moving speed of the film clamp 120.

When the distance DT increases and the angle ANG decreases due to a decrease in the tension of the film stamp 22, the controller 190 may move the film clamp 120 to the right or up in FIG. 1. For example, when the film clamp 120 and the roller 130 moves in a specific direction in a manufacturing process, the controller 190 may increase a moving speed of the film clamp 120.

The controller 190 may set target values of the angle ANG and the distance DT.

For example, when the angle ANG is greater than the target value or the distance DT is smaller than the target value, the controller 190 moves the film clamp 120 to the left or down in FIG. 1. For example, when the angle ANG is smaller than the target value or the distance DT is greater than the target value, the controller 190 moves the film clamp 120 to the right or up in FIG. 1.

In an embodiment, the camera 140 includes a first camera for measuring the angle ANG and a second camera for measuring the distance DT. The first camera may be positioned adjacent to the roller 130 for the purpose of measuring the angle ANG finely. In an embodiment, the film clamp 120 is located outside the field of view of the first camera.

In an embodiment, both the roller 130 and the film clamp 120 are within the field of view of the second camera for the purpose of measuring the distance DT. In an embodiment, a second distance between the roller 130 and the second camera is greater than a first distance between the roller 130 and the first camera.

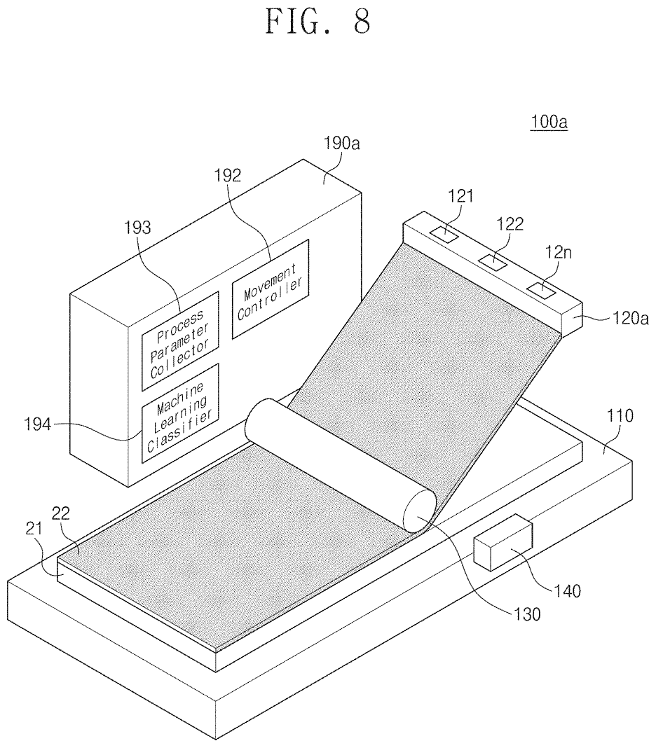

FIG. 8 is a view illustrating a semiconductor imprint device 100a according to an exemplary embodiment of the inventive concept. Referring to FIG. 8, the semiconductor imprint device 100a includes the stage 110, a film clamp 120a, the roller 130, the camera 140, and a controller 190a.

Configurations and operations of the stage 110, the roller 130, and the camera 140 may be identical to those described with reference to FIGS. 1 to 7. Thus, additional description will be omitted to avoid redundancy.

The film clamp 120a includes sensors 121 to 12n which measure tensions of the film stamp 22 at a nozzle where the film clamp 120a provides the film stamp 22. The sensors 121 to 12n measure the tensions of the film stamp 22 at various positions of the film stamp 22. The measured tensions (or tension information) may be provided to the controller 190a.

In an embodiment, the controller 190a adjusts a position of the film clamp 120a based on machine learning. The controller 190a includes the movement controller 192, a process parameter collector 193, and a machine learning classifier 194.

The process parameter collector 193 may collect various parameters associated with an imprinting process. The process parameter collector 193 may include various sensors collecting parameters associated with a process (e.g., an imprinting process).

For example, the process parameter collector 193 may collect tensions sensed by the sensors (or tension sensors) 121 to 12n. The process parameter collector 193 may collect a temperature or humidity which may have an influence on the tension of the film stamp 22. For example, additional sensors may be present to sense the temperature and/or the humidity.

Depending on a characteristic of the semiconductor imprint device 100a or a characteristic of the imprinting process, the process parameter collector 193 may collect parameters which have an influence on the tension of the film stamp 22, for example, parameters associated with a moving speed of the film clamp 120a and the roller 130 or a moving speed of the stage 110, a position of the film clamp 120a within a movable range of the film clamp 120a, and a position of the roller 130 or the film clamp 120a on the substrate 21.

The process parameter collector 193 may collect a parameter associated with the number of times that the film stamp 22 is used. For example, the number of times that the film stamp 22 is used may have an influence on the tension of the film stamp 22. For example, the number of times exceeding a certain threshold may indicate that the film stamp 22 has deteriorated and needs to be replaced. Also, the process parameter collector 193 may collect parameters of the angle ANG and the distance DT, as described with reference to FIGS. 4 to 7, from an image captured by the camera 140.

The process parameter collector 193 may collect one or more of the above-described parameters and may provide the collected parameters to the machine learning classifier 194. The machine learning classifier 194 may perform machine learning-based classification by using the parameters collected by the process parameter collector 193.

For example, the machine learning classifier 194 may predict (or classify) whether the tension of the film stamp 22 will increase, will decrease, or will be maintained. Depending on a result of the prediction, the machine learning classifier 194 may output an adjustment parameter for maintaining the tension of the film stamp 22 within a specific range. For example, if the controller 190a predicts that the tension will increase beyond the specific range, the controller 190a can decrease the tension of the film stamp 22. For example, if the controller 190a predicts that the tension will decrease below the specific range, the controller 190a can increase the tension of the film stamp 22.

In another example, the machine learning classifier 194 may predict (or classify) the movement or position of the film clamp 120a for maintaining the tension of the film stamp 22 within the specific range. For example, the machine learning classifier 194 may generate a model used to predict the movement or position of the film clamp 120a for maintaining the tension within the specific range. Depending on a result of the prediction, the machine learning classifier 194 may output the adjustment parameter.

The movement controller 192 may receive the adjustment parameter from the machine learning classifier 194. The movement controller 192 may adjust the movement of the film clamp 120a depending on the adjustment parameter.

According to an embodiment of the inventive concept, the machine learning-based prediction (or classification) is performed by using various parameters of the imprinting process. The movement or position of the film clamp 120a is adjusted depending on a result of the prediction (or classification). Accordingly, the tension of the film stamp 22 may be maintained within the specific range.

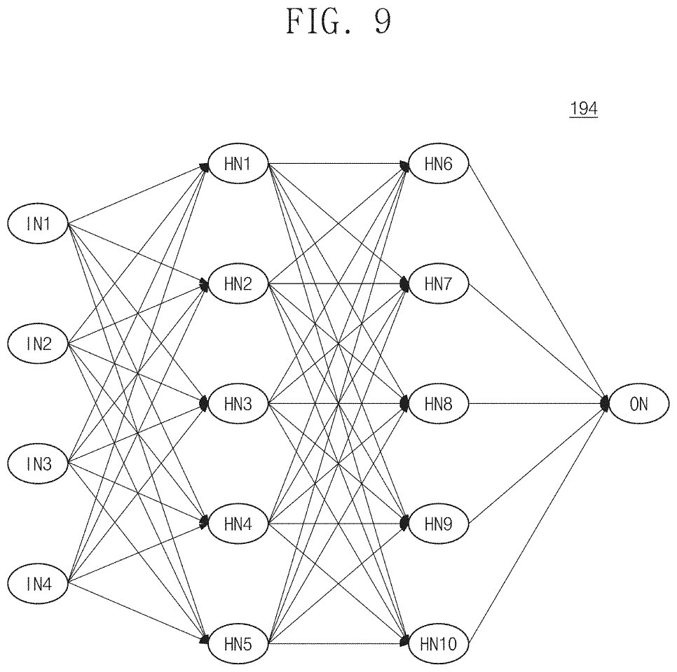

FIG. 9 is a view illustrating an example where the machine learning classifier 194 performs machine learning-based classification. In an embodiment, the machine learning classifier 194 may be based on deep learning such as a neural network, am artificial neural network (ANN), a convolution neural network (CNN), or a recursive neural network (RNN).

Referring to FIGS. 8 to 9, the machine learning classifier 194 includes first to fourth input nodes IN1 to IN4, first to tenth hidden nodes HN1 to HN10, and an output node ON. The number of input nodes, the number of hidden nodes, and the number of output nodes may be determined in advance upon constructing the neural network.

The first to fourth input nodes IN1 to IN4 form an input layer. The first to fifth hidden nodes HN1 to HN5 form a first hidden layer. The sixth to tenth hidden nodes HN6 to HN10 form a second hidden layer. The output node ON forms an output layer. The number of hidden layers may be determined in advance upon constructing the neural network.

Parameters collected by the process parameter collector 193 may be input to the first to fourth input nodes IN1 to IN4. Parameters of different kinds may be input to different input nodes. The parameters of the input nodes are transferred to the first to fifth hidden nodes HN1 to HN5 of the first hidden layer, with weights applied to the parameters.

An input of each of the first to fifth hidden nodes HN1 to HN5 is transferred to the sixth to tenth hidden nodes HN6 to HN10 of the second hidden layer, with weights applied to the input thereof. Inputs of the sixth to tenth hidden nodes HN6 to HN10 are transferred to the output node ON, with weights applied to the inputs thereof. Information of the output node ON may be output as the adjustment parameter of the film clamp 120a.

For example, machine learning may be performed based on various parameters and a state (e.g., tension) of the film clamp 120a or the movement of the film clamp 120a, which is determined depending on the various parameters. For example, the machine learning may be performed by an external computer.

In the machine learning, a change in the tension of the film stamp 22 may be predicted (or classified) by using various parameters. A result of the prediction may be compared with an actual tension value. The weights of the first to fourth input nodes IN1 to IN4 and the first to tenth hidden nodes HN1 to HN10 may be adjusted depending on a result of the comparison. The weights of the first to fourth input nodes IN1 to IN4 and the first to tenth hidden nodes HN1 to HN10 may be determined through iterations of the machine learning.

Alternatively, by using various parameters, a change in the tension of the film stamp 22 and the model movement of the film clamp 120a may be predicted (or classified). The predicted movement may be compared with the actual movement of the film clamp 120a. The weights of the first to fourth input nodes IN1 to IN4 and the first to tenth hidden nodes HN1 to HN10 may be adjusted depending on a result of the comparison. The weights of the first to fourth input nodes IN1 to IN4 and the first to tenth hidden nodes HN1 to HN10 may be determined through iterations of the machine learning.

In an embodiment, the machine learning has completed when the weights are determined. When the machine learning has completed, the trained machine learning classifier 194 may be mounted on the controller 190a. Through the machine learning, the controller 190a may predict (or classify) the tension of the film stamp 22 or the movement of the film clamp 120a, which is determined according to a process parameter. Depending on a result of the prediction (or classification), the machine learning classifier 194 may output the adjustment parameter.

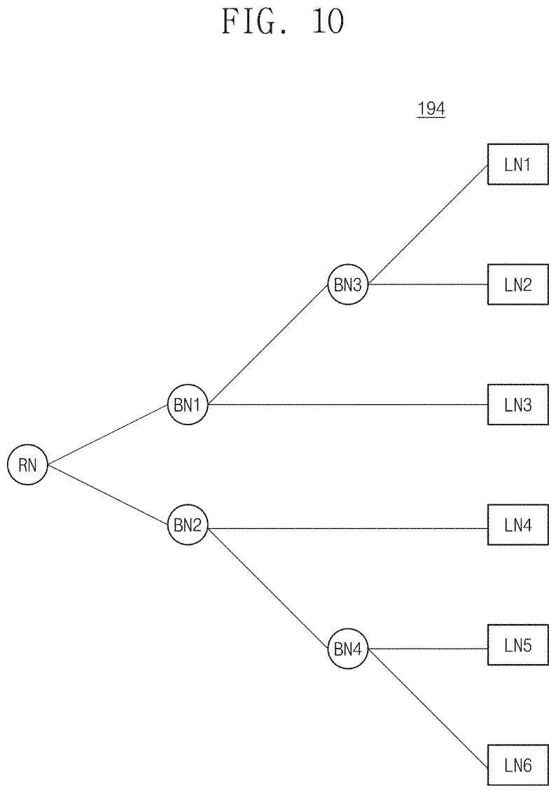

FIG. 10 is a view illustrating an example where the machine learning classifier 194 performs machine learning-based classification. In an embodiment, the machine learning classifier 194 is based on a decision tree. Referring to FIGS. 8 and 10, the machine learning classifier 194 includes a root node RN, first to fourth branch nodes BN1 to BN4, and first to sixth leaf nodes LN1 to LN6. The root node RN, the first to fourth branch nodes BN1 to BN4, and the first to sixth leaf nodes LN1 to LN6 may be connected through branches.

In each of the root node RN and the first to fourth branch nodes BN1 to BN4, a comparison may be performed with respect to at least one of the parameters collected by the process parameter collector 193. One of a plurality of branches connected to each node is selected depending on a result of the comparison. When a next branch node is connected to the selected branch, a comparison may be further performed at the next branch node.

When a leaf node has been connected to the selected branch, information of the leaf node may be selected. For example, the first to sixth leaf nodes LN1 to LN6 may include information about movements of the film clamp 120a. The machine learning classifier 194 may output movement information of the selected leaf node as the adjustment parameter.

In another example, the first to sixth leaf nodes LN1 to LN6 include information about a change in the tension of the film stamp 22. The machine learning classifier 194 may determine a change in the tension from the information of the selected leaf node. The machine learning classifier 194 may output the adjustment parameter for compensating for the change in the tension.

For example, machine learning may be performed based on various parameters and a state (e.g., tension) of the film clamp 120a or the movement of the film clamp 120a, which is determined depending on the various parameters. For example, the machine learning may be performed by an external computer.

In the machine learning, a change in the tension of the film stamp 22 may be predicted (or classified) by using various parameters. A result of the prediction may be compared with an actual tension value. A threshold value which is compared with a process parameter at the root node RN and the first to fourth branch nodes BN1 to BN4 may be adjusted depending on a result of the comparison. Threshold values of the root node RN and the first to fourth branch nodes BN1 to BN4 may be determined through iterations of the machine learning.

Alternatively, by using various parameters, a change in the tension of the film stamp 22 and the model movement of the film clamp 120a may be predicted (or classified). The predicted movement may be compared with the actual movement of the film clamp 120a. A threshold value which is compared with a process parameter at the root node RN and the first to fourth branch nodes BN1 to BN4 may be adjusted depending on a result of the comparison. Threshold values of the root node RN and the first to fourth branch nodes BN1 to BN4 may be determined through iterations of the machine learning.

In an embodiment, the machine learning has completed when the weights are determined. When the machine learning has completed, the trained machine learning classifier 194 may be mounted on the controller 190a. Through the machine learning, the controller 190a may predict (or classify) the tension of the film stamp 22 or the movement of the film clamp 120a, which is determined according to a process parameter. Depending on a result of the prediction (or classification), the machine learning classifier 194 may output the adjustment parameter.

In an embodiment, a parameter, which has the highest selectivity, from among the parameters collected by the process parameter collector 193 may be compared at the root node RN. For example, a parameter which has the greatest influence on the tension of the film stamp 22 may be compared at the root node RN.

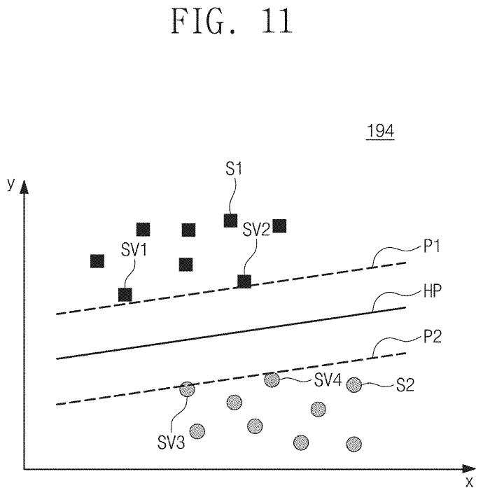

FIG. 11 is a view illustrating another example in which the machine learning classifier 194 performs a machine learning-based classification. In an embodiment, the machine learning classifier 194 is based on a support vector machine. In FIG. 11, each of a horizontal axis “x” and a vertical axis “y” represent parameters collected by the process parameter collector 193.

For example, when “n” parameters are used, the machine learning classifier 194 may perform n-dimensional classification.

Referring to FIGS. 8 and 11, in the machine learning, samples may be arranged depending on process parameters. For example, first samples 51 of a square may represent cases where the tension increases, and second samples S2 of a circle may represent cases where the tension decreases. In another example, the first samples S1 may represent cases where the tension is normal (e.g., within a certain range), and the second samples S2 may represent cases where the tension is abnormal (e.g., excessive or too small).

In another example, the first samples S1 may represent cases where the film clamp 120a moves in a first direction, and the second samples S2 may represent cases where the film clamp 120a moves in a second direction.

In the machine learning, a hyperplane HP which is most distant from the first samples S1 and also most distant from the second samples S2 may be determined. The hyperplane HP may be determined as being between a first plane P1 defined by the first samples S1 and a second plane P2 defined by the second samples S2.

First samples, which are used to define the first plane Pl, from among the first samples S1 may be a first support vector SV1 and a second support vector SV2. Second samples, which are used to define the second plane P2, from among the second samples S2 may be a third support vector SV3 and a fourth support vector SV4. When the machine learning has completed, the trained machine learning classifier 194 may be mounted on the controller 190a.

Depending on whether a current state represented by process parameters belongs to any side with respect to the hyperplane HP, the machine learning classifier 194 may classify a change in the tension of the film stamp 22 or may classify the movement of the film clamp 120a.

A description is given in FIG. 11 as the machine learning for determining the hyperplane HP and the classification using the hyperplane HP are performed. However, the machine learning classifier 194 may perform machine learning for determining a curved surface and classification using the curved surface. When “n” process parameters are applied, the machine learning classifier 194 may perform machine learning for determining an n-dimensional curved surface and classification using the n-dimensional curved surface.

A description is given in FIG. 11 as two kinds of samples are used for machine learning and classification. However, the machine learning classifier 194 may perform machine learning for determining a plane or a curved surface by using three or more samples and classification using the plane or the curved surface.

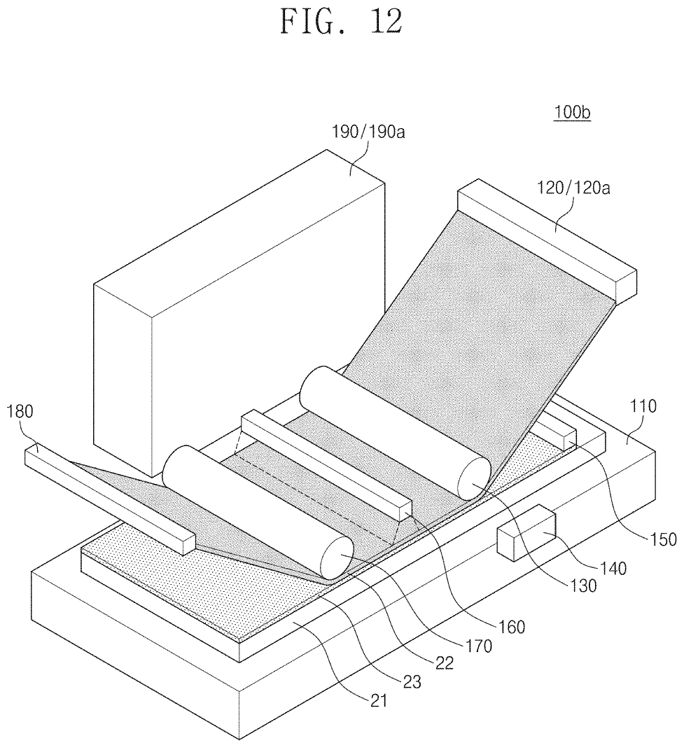

FIG. 12 is a view illustrating a semiconductor imprint device 100b according to an exemplary embodiment of the inventive concept. Referring to FIG. 12, the semiconductor imprint device 100b includes the stage 110, the film clamp 120/120a, the roller 130, the camera 140, an applicator 150, a lamp 160 (e.g., a light source), a rear roller 170, a film collector 180, and a controller 190/190a.

As described with reference to FIGS. 1 to 11, the stage 110 may be configured to support the substrate 21. The applicator 150 (e.g., a resin applicator) is configured to apply a resin 23 onto the substrate 21. For example, the resin 23 may include a photo-curable material configured to be cured by light. The applicator 150 may apply the resin 23 onto the substrate 21 uniformly.

The film clamp 120/120a may be the film clamp 120 described with reference to FIGS. 1 to 7 or the film clamp 120a described with reference to FIGS. 8 to 11. The film clamp 120/120a may apply the film stamp 22 onto the resin 23.

A configuration and an operation of the roller 130 may be identical to those described with reference to FIGS. 1 to 11 except that the roller 130 applies pressure so that the film stamp 22 is brought into close contact with the resin 23. When the roller 130 applies pressure to the film stamp 22, the pattern of the film stamp 22 is transferred to the resin 23.

The lamp 160 projects light onto the resin 23 through the film stamp 22. For example, the film stamp 22 may be implemented with a material which transmits light. In an embodiment, the film stamp 22 is implemented with a translucent material. When the light is projected, the resin 23 may be cured with the pattern of the film stamp 22 transferred.

In an embodiment, the rear roller 170 applies pressure to the film stamp 22 so that the film stamp 22 is not separated from the substrate 21 while the resin 23 is cured by the light. For example, as described with reference to FIG. 2, the rear roller 170 may have the same structure as the roller 130 and may be adjusted in the same manner as the roller 130.

In an embodiment, the film collector 180 separates and collects the film stamp 22 from the substrate 21 and the resin 23. For example, the film collector 180 may include one or more rollers which wind the film stamp 22.

The controller 190/190a may have the same function as the controller 190 described with reference to FIGS. 1 to 7 or the same function as the controller 190a described with reference to FIGS. 8 to 11. In addition to the above description, the controller 190/190a may adjust movements of the applicator 150, the lamp 160, the rear roller 170, and the film collector 180.

For example, in an imprinting process, the controller 190/190a may move the applicator 150, the lamp 160, the rear roller 170, and the film collector 180 in a specific direction together with the film clamp 120/120a and the roller 130. In another example, in the imprinting process, the controller 190/190a may move the stage 110 in a specific direction.

As described above, the semiconductor imprint device 100, 100a, or 100b according to an embodiment of the inventive concept captures an image associated with the roller 130 and the film stamp 22 and adjusts the movement or position of the film clamp 120 or 120a by using information of the image so that the tension of the film stamp 22 is maintained within a specific range. Accordingly, with regard to the semiconductor imprint device 100, 100a, or 100b, the yield (e.g., the quantity of semiconductor devices manufactured by the semiconductor imprint device 100, 100a, or 100b) is improved, and the manufacturing costs is reduced.

According to at least one embodiment of the inventive concept, in the process of manufacturing a semiconductor device, the tension of a film stamp is maintained within a specific range by using an image of a film stamp. Accordingly, a semiconductor imprint device having improved yield and reduced manufacturing costs and a manufacturing method of the semiconductor imprint device are provided.

While the inventive concept has been described with reference to exemplary embodiments thereof, it will be apparent to those of ordinary skill in the art that various changes and modifications may be made thereto without departing from the spirit and scope of the inventive concept.

1. A semiconductor imprint device comprising:
a stage configured to support a substrate,
a film clamp configured to apply a film stamp onto the substrate, the film stamp including a pattern for forming a semiconductor device;
a roller configured to apply pressure to the film stamp disposed on the substrate so that the pattern is transferred to the substrate;
a first camera configured to capture a first image of the roller and the film stamp; and
a controller configured to adjust a position of the film clamp by using the first image.

2. The semiconductor imprint device of claim 1, wherein the film clamp is moved in a specific direction to apply the film stamp onto the substrate, and
wherein the roller applies the pressure to the film stamp while being moved in the specific direction.

3. The semiconductor imprint device of claim 2, wherein the controller adjusts a moving speed of the film clamp to adjust the position.

4. The semiconductor imprint device of claim 2, wherein the controller is configured to move the roller so that the pressure is based on only a weight of the roller.

5. The semiconductor imprint device of claim 1, wherein the controller is configured to adjust a height of the film clamp above the stage.

6. The semiconductor imprint device of claim 1, wherein the controller is configured to adjust a distance between the film clamp and the roller.

7. The semiconductor imprint device of claim 1, wherein the controller is configured to adjust the position of the film clamp so that a tension of the film stamp is maintained within a specific range at a specific interface of the film stamp, at which the film stamp and the roller are in contact with each other.

8. The semiconductor imprint device of claim 1, wherein the controller is configured to adjust the position of the film clamp so that an angle between a normal of the roller and a line perpendicular to the substrate is maintained within a specific range at a specific interface of the film stamp, at which the film stamp and the roller are in contact with each other.

9. The semiconductor imprint device of claim 1, wherein the controller is configured to adjust the position of the film clamp so that a distance between the film stamp and a line connecting the film clamp and a specific interface of the film stamp, at which the film stamp and the roller are in contact with each other, is maintained within a specific range.

10. The semiconductor imprint device of claim 1, wherein the controller is configured to adjust the position of the film stamp based on machine learning by using the first image.

11. The semiconductor imprint device of claim 10, wherein the film clamp includes a tension sensor configured to measure a tension of the film stamp, and
wherein the controller is configured to adjust the position of the film stamp based on the machine learning by further using the measured tension.

12. The semiconductor imprint device of claim 10, further comprising:
sensors configured to measure a temperature and a humidity,
wherein the controller is configured to adjust the position of the film stamp based on the machine learning by further using the measured temperature and the measured humidity.

13. The semiconductor imprint device of claim 10, wherein the controller is configured to adjust the position of the film stamp based on the machine learning by further using at least one of i) moving speeds of the film clamp and the roller, ii) positions of the film clamp and the roller on the substrate, and iii) a number of times the film stamp is used.

14. The semiconductor imprint device of claim 10, wherein the controller obtains, from the first image, an angle between a line perpendicular to the substrate and a normal of the roller at a specific interface of the film stamp, at which the film stamp and the roller are in contact with each other, and a distance between the film stamp and a line connecting the interface and the film clamp, and is configured to adjust the position of the film stamp based on the machine learning by using the angle and the distance.

15. The semiconductor imprint device of claim 1, further comprising:
a second camera configured to capture a second image of the roller and the film stamp,
wherein a distance between the second camera and the roller is different from a distance between the first camera and the roller.

16. A semiconductor imprint device comprising:
a stage configured to support a substrate;
an applicator configured to apply a resin onto the substrate;
a film clamp configured to apply a film stamp onto the resin, the film stamp including a pattern for forming a semiconductor device;
a first roller configured to apply a first pressure to the film stamp disposed on the substrate so that the pattern is transferred to the resin;
a second roller configured to apply a second pressure to the film stamp so that contact of the film stamp and the resin between the first roller and the second roller is maintained;
a lamp configured to project light onto the resin through the film stamp between the first roller and the second roller;
a camera configured to capture an image of the first roller and the film stamp; and
a controller configured to adjust a position of the film stamp by using the image so that a tension of the film stamp between the first roller and the film clamp is maintained within a specific range.

17. The semiconductor imprint device of claim 16, wherein the controller is configured to perform a machine learning-based classification by using the image and adjust the position of the film stamp based on a result of the classification.

18. A method of operating a semiconductor imprint device which includes a film clamp and a roller, the method comprising:
applying, by the film clamp, a film stamp onto a substrate;
applying, by the roller, pressure to the film stamp;
capturing, by a camera of the semiconductor imprint device, an image of the roller and the film stamp; and
adjusting, by a controller of the semiconductor imprint device, a position of the film clamp by using the image.

19. The method of claim 18, wherein the film stamp includes a pattern for forming a semiconductor device that is transferred to the substrate as a result of applying the pressure and adjusting of the position.

20. The method of claim 18, wherein the adjusting comprises:
performing machine learning-based classification by using the image; and
calculating the position based on a result of the classification.

21-23. (canceled)
